(19) United States
(12) Patent Application Publication
(10) Pub. No.: US 2012/0080071 A1
(43) Pub. Date: Apr. 5, 2012

(54) SYSTEM AND METHOD FOR GENERATING ENERGY FROM PARKING SHADE STRUCTURES

(76) Inventors: Steve Kimbriel, Tucson, AZ (US); James Crawford Shields, Estero, FL (US)

(21) Appl. No.: 12/896,129

(22) Filed: Oct. 1, 2010

(51) Int. Cl. H01L 31/052

(52) U.S. Cl. 136/246

(57) ABSTRACT

A system for automatically providing shade to a parking space and transducing incident energy into electricity for storage and redistribution, including a generally vertically extending first support member having a proximal end anchored to the ground and an oppositely positioned distal end and an energy transaction portion connected near the proximal end of the first support member, which further includes a housing, a microprocessor portion positioned in the housing and operationally connected to a computer network, an energy metering portion positioned in the housing and operationally connected to the microprocessor, an energy inlet portion operationally connected to the housing and the energy metering portion, and an energy outlet portion operationally connected to the housing and the energy metering portion. The system further includes an energy storage portion operationally connected to the energy metering portion, energy inlet portion and to the energy outlet portion, and a solar panel for transducing incident sunlight into electricity and for providing parking shade operationally connected near the distal end of the first support member and to the energy inlet portion.

### TECHNICAL FIELD

The novel technology relates generally to the field of energy, and, more particularly, to a commercial method and apparatus for providing, capturing, transducing, storing, and redistributing energy in response to consumer requests.

### BACKGROUND

It is widely considered that energy will be the most important factor influencing the shape of society in the 21st century. The cost and availability of energy will not only have an impact on the quality of life of the individual, but will govern the interactions of national economies, dominate the relationships between countries, and the determine the stability of the environment. Convenient sources or energy are becoming increasingly scarce. Such sources include oil, biofuels, wind, hydroelectric, geothermal, and solar. While all of these sources are renewable over time, the renewal periods for some (solar, wind, hydroelectric) are faster than the periods for others (oil).

As local and global populations increase, so does the demand for energy. Further, as nations become increasingly industrialized, so increases their demand for energy. Likewise, as energy consumption increases, so does the pollution resulting from the acquisition, processing and refinement of energy resources as well as from the consumption of the same. The current rates of global industrialization and population growth are in turn driving the harvesting and consumption of energy at unsustainable levels.

Man's use of energy has traditionally been very inefficient. Much of the waste associated with the consumption of fuels constitutes partially depleted but still viable energy sources. Thus far, energy resources have been squandered through shortsightedness and wasteful consumption.

Thus, there is a need for an efficient system of energy collection and redistribution. The present novel technology arises from an attempt to address this need.

### SUMMARY

The present novel technology relates to a system and method for capturing, transducing, storing, and providing energy. One object of the present novel technology is to provide an improved means for redistributing energy. Related objects and advantages of the present novel technology will be apparent from the following description.

### BRIEF DESCRIPTION OF THE DRAWINGS

FIG. 1 is a perspective view of a system for providing and renting shaded parking space while capturing and transducing solar energy for resale according to a first embodiment of the present novel technology.

FIG. 2 is an enlarged perspective view of a solar shade assembly according to the embodiment of FIG. 1.

FIG. 3 is an enlarged partial view of the assembly at FIG. 2.

FIG. 4 is a perspective view of an alternate assembly according to the embodiment of FIG. 1.

FIG. 5 is an enlarged front elevation view of an energy exchange kiosk according to the embodiment of FIG. 1.

### DESCRIPTION OF THE PREFERRED EMBODIMENTS

For the purposes of promoting an understanding of the principles of the novel technology and presenting its currently understood best mode of operation, reference will now be made to the embodiments illustrated in the drawings and specific language will be used to describe the same. It will nevertheless be understood that no limitation of the scope of the novel technology is thereby intended, with such alterations and further modifications in the illustrated device and such further applications of the principles of the novel technology as illustrated therein being contemplated as would normally occur to one skilled in the art to which the novel technology relates.

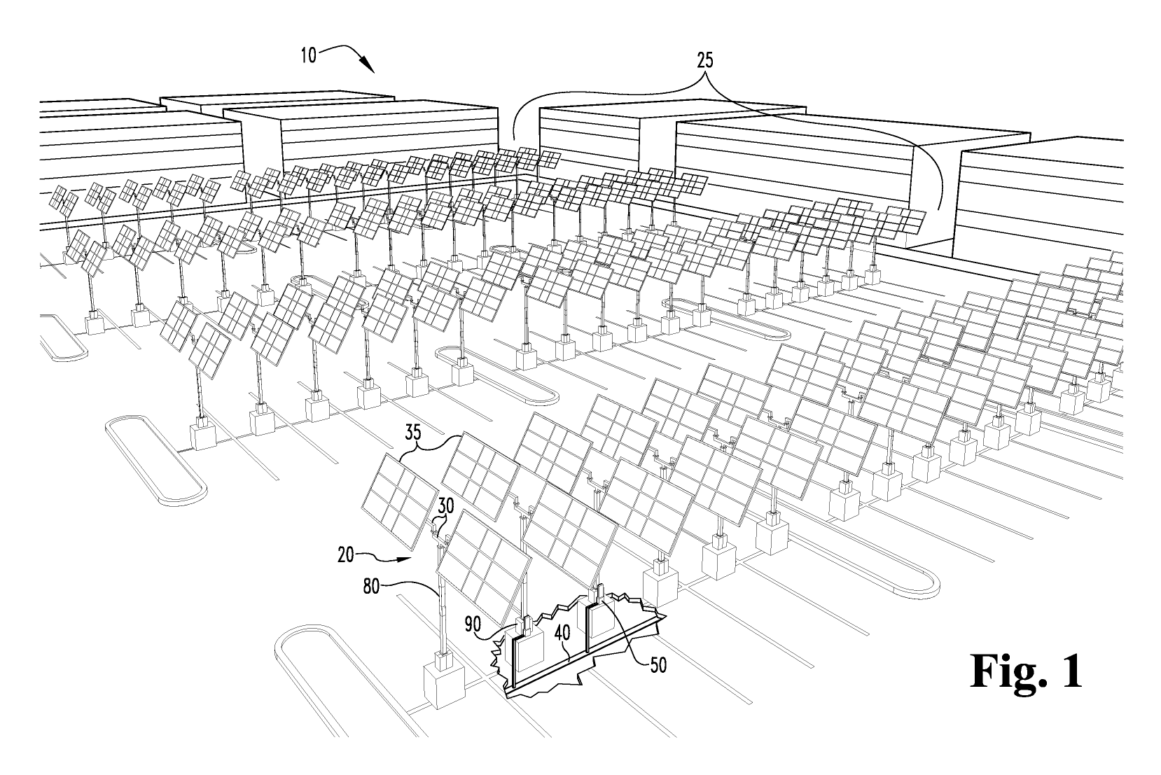

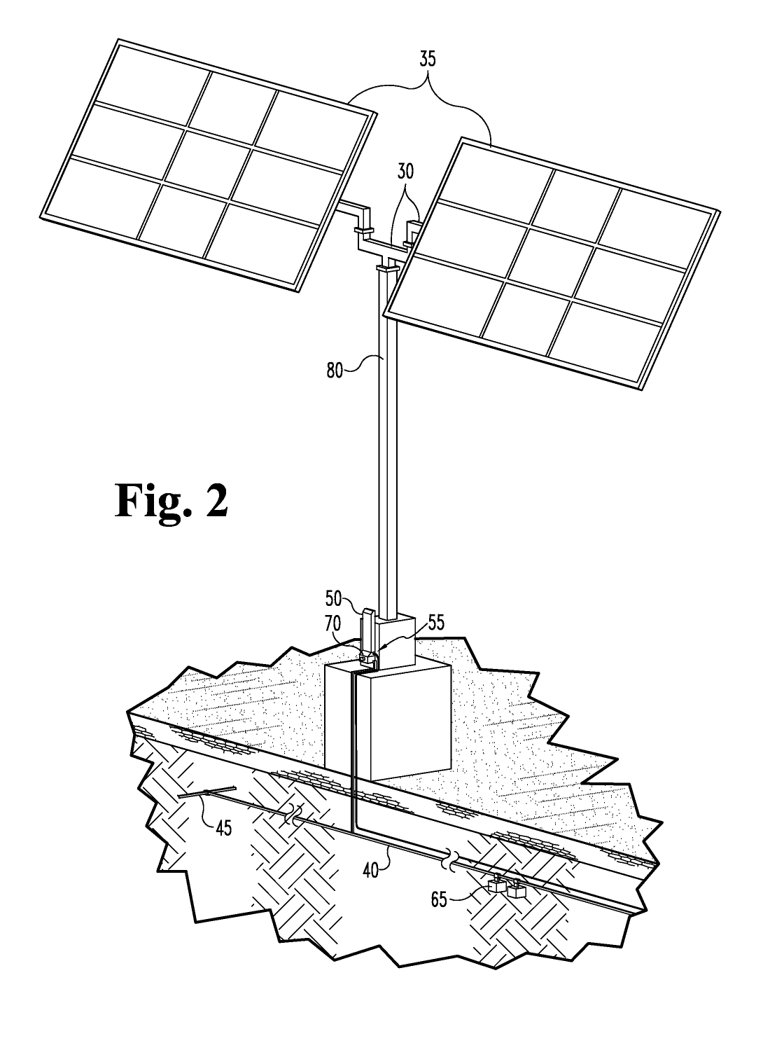

FIGS. 1-3 illustrate a first embodiment of the present novel technology, a system 10 for simultaneously providing shade and harvesting, storing, and redistributing energy that includes a plurality of modular and interconnectable solar shade units 20 defining an array 25 for placement in parking lots (particularly in high sunlight/high heat regions) to provide the benefit of parking shade while simultaneously harvesting light and/or heat energy for transduction into electricity. Each parking space will be shaded by a modular unit 20, typically consisting of a support member 30 and an energy transduction source 35, typically a solar panel, set extending therefrom. The modular units 20 are typically electrically connected 40 to one another, and are more typically connected into the local power grid 45.

Further, each unit 20 typically includes a transaction or kiosk portion 50 electrically connected to the solar panel 35 as well as electrically connected to the local power grid 45. The kiosk portion 50 further includes a microprocessor portion 55 for measuring parking time and receiving payment. Typically, the microprocessor 55 functions as a credit card processing unit and is connected to a computer network, such as the Internet, for performing authorization and banking transaction events. Additionally, one or more retail outlets on whose parking lot the array 25 is positioned may provide a validation code to offset some or all of the parking charges (the amount of offset may be dependent upon dollars spent in the store) for patrons. Alternately, such credit may be accrued on account, and accessed by an account number, swipe card, or the like. The system 10 may further include rechargeable batteries 65 connected to outlets 70 as well as connected to the solar panels 75 so as to collect and store some of the transduced electricity. Moreover, the microprocessor portion 55 is typically at least partially powered by the transduced solar energy. The microprocessor portion 55 may be include only single microprocessor unit, or may include a plurality of microprocessors and/or metering and/or measurement devices operationally connected to one another.

The system 10 may further include charging outlets 70 to which battery operated or electric vehicles or the like may be connected. Typically, a charging outlet 70 is connected to the kiosk portion 50, and is more typically operationally connected to the credit card microprocessing portion 55, such that the electricity used to charge the vehicle may be measured and paid for. In this embodiment, the kiosk portion 50 not only measures parking time but also electric current dispensed, and the microprocessor portion 55 processes payment for time and/or electricity purchased.

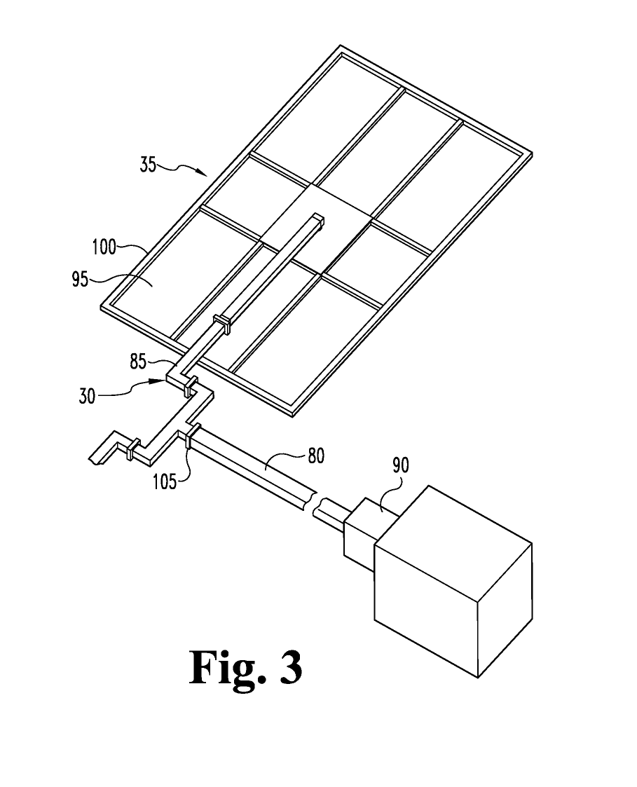

The support structure 30 is illustrated in greater detail in FIG. 3. The support structure 30 typically includes a central support member 80 extending upwardly from the ground and an armature portion 85 extending generally horizontally outwardly from the central support member 80 and connecting to a solar panel 35. The central support member 80 is typically anchored by an anchor member 90 connected at its proximal end, with the armature portion 85 connected at the opposite, distal end. The anchor member 90 may be permanently affixed into the ground or parking lot surface, or, alternately, may be removably anchored and portable.

The solar panel 35 typically includes a plurality of smaller, individual solar collectors 95 supported by a structural framework 100. The armature portion 85 typically includes one or more swivelable, pivotable and/or rotatable joints for adjusting and positioning the solar panel 35, typically with at least about 90 degree rotation, more typically with at least about 180 degree rotation, and still more typically with substantially 360 degree rotation around the x-, y-, and/or z-axes, or at least a close approximation of the same.

While the energy transduction source 35 discussed above is a photoelectric solar panel, the energy source 35 could be of any convenient type, such as a thermoelectric transducer array, a thermal collector using a liquid medium for storing heat for conversion into electricity, or the like.

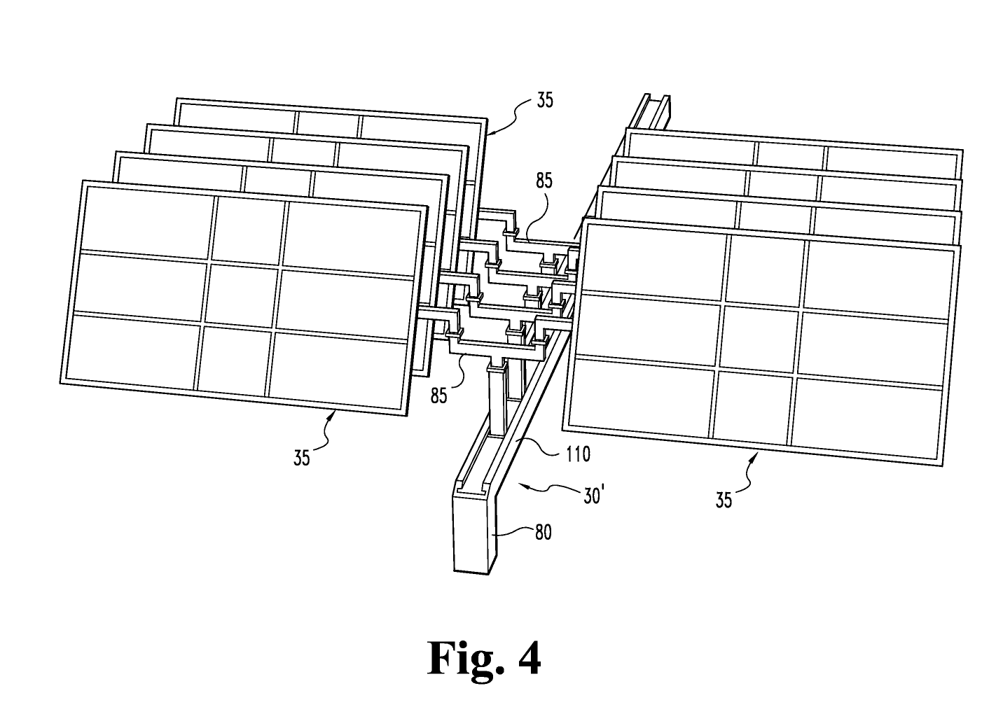

FIG. 4 illustrates an alternate embodiment support structure 30′, having a raised horizontal support member 110 connected to a the ground via a vertical support member 80, and also connected to a plurality of armature portions 85, each of which is connected to at least one solar panel 35. One, or, more typically, a plurality of vertical support members 80 extend from respective anchor members 90, as in the previously discussed embodiment, to the horizontal support member 110. The horizontal support member 110 connects to one, or, more typically, a plurality of respective armature portions 85. The armature portions 85 are typically slidingly connected to the support member 110, such as through a slotted connection interface 115, and are thus able to be adjustably moved or positioned along the horizontal support member 110. The respective solar panels 35 are connected in electric communication, such as through electrical conduits extending through the structural members 80, 85, 110, with the grid 45 and/or batteries 65 and/or the like.

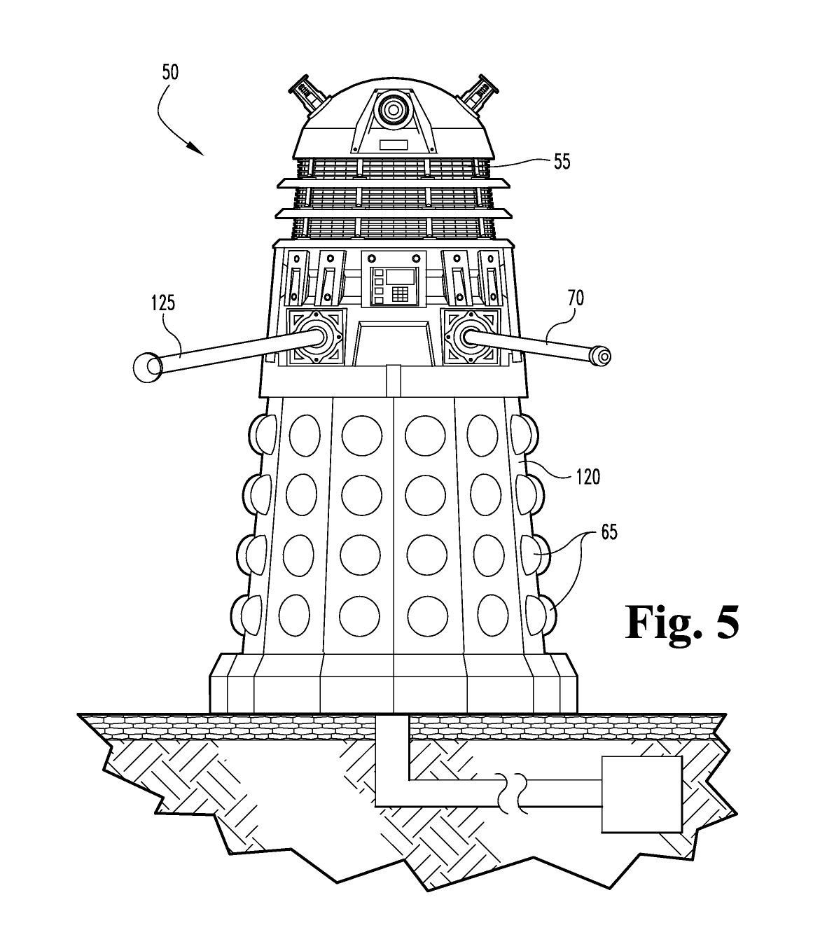

FIG. 5 illustrates the kiosk portion 50 in greater detail. The kiosk portion includes a housing 120, typically made of a structural material such as steel, aluminum, or the like, for containing, protecting and isolating the microprocessor portion 55, the charging outlets 70, and like hardware. In some embodiments, in addition to a charging outlet 70 for providing energy for purchase and/or use, the kiosk portion 50 also includes an energy collector or inlet 125 for receiving energy. The inlet 125 is likewise operationally connected to the microprocessor 55, such that energy received by the kiosk 50 may be measured and appropriately credited. The inlet 125 may be of a universal or generic design, or may be an array of connectors for receiving and/or transducing energy in a variety of formats for storage in the electrical batteries 65. The kiosk portion 50 may also house storage batteries 65 and/or may be operationally connected to batteries 65 located away from the kiosk 50. The batteries 65 are typically electric energy storage cells, but may alternately store energy in other ways, such as gravitationally, thermally, or the like.

In operation, the system 10 functions as follows. The system 10 receives 200 energy from one or more power sources 35, 45, 125. Energy received 200 through the inlet 125 is measured 210 by the microprocessor 55 and the energy vendor is identified 215 and credited 220. Crediting 220 may be in the form of monetary compensation dispensed as cash, as a credit to the vendor's bank account, or the like. Energy received 200 is stored 225 in the grid 45, the batteries 65, or both. Energy is dispensed 240 to a user through the outlet 70. A user is identified 215 and is debited 230. Debiting 230 may be done as a cash transaction, as an electronic debit or credit card transaction, as a direct bank account debit, or the like. Energy is dispensed 240 via the outlet 70. The outlet 70 may provide electric charge to a vehicle, a battery, directly to one or more electrical appliances, an entire household or business, or the like. Typically, crediting 220 and debiting 230 transactions include input of a security check or authorization code for verification, and utilize customary security precautions.

In one embodiment, the kiosk 50 may be located at a vehicular charging or fueling station. Electric vehicles low on charge would operationally connect their batteries to the outlet 70 and receive an electrical charge in exchange for payment. Likewise, vehicles having excess charge may operationally connect to the inlet 125 and supply energy to the kiosk for storage in the batteries 65 in exchange for payment or credit.

In another embodiment, energy kiosks 50 are provided at residential locations. All power consumed by the residential location would be supplied by the kiosk 50 through the outlet(s) 70. Conversely, energy generated or harvested at the residence, such as electricity generated by wind turbine, solar transduction, biomass reaction, or the like, is channeled into an inlet 125, measured and stored in storage media 65. The residential occupant is compensated for the metered energy input, such as by monetary credit to a bank account, energy supply credits, or the like, with the kiosk 50 provider would typically charge a small transaction fee for the services.

Further, the energy kiosk provider would typically also provide appropriate energy harvesting equipment 35, such as solar panels, wind and/or water turbines, biomass reactors, or the like, along with the kiosk 50 to the residential occupant such that the occupant might be able to maximize energy efficiency. Again, a fee would be levied for the equipment use, but such a fee might be offset by tax credits, rebates, grants and the like.

In this way, the residential consumer will both be made aware of his energy consuming habits while at the same time utilizing more efficient energy generation, storage and recycling strategies. Likewise this approach may be taken with businesses, communities, neighborhoods, and the like.

While the novel technology has been illustrated and described in detail in the drawings and foregoing description, the same is to be considered as illustrative and not restrictive in character. It is understood that the embodiments have been shown and described in the foregoing specification in satisfaction of the best mode and enablement requirements. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the novel technology are desired to be protected.

What is claimed is:

1. A system for automatically providing shade to a parking space and transducing incident energy into electricity for storage and redistribution, comprising:
a generally vertically extending first support member having a proximal end anchored to the ground and an oppositely positioned distal end;
an energy transaction portion connected near the proximal end of the first support member and further comprising;
a housing;
a microprocessor portion positioned in the housing and operationally connected to a computer network;
an energy metering portion positioned in the housing and operationally connected to the microprocessor;
an energy inlet portion operationally connected to the housing and the energy metering portion; and
an energy outlet portion operationally connected to the housing and the energy metering portion; and
an energy storage portion operationally connected to the energy metering portion, energy inlet portion and to the energy outlet portion; and
a solar panel for transducing incident sunlight into electricity and for providing parking shade operationally connected near the distal end of the first support member and to the energy inlet portion.

2. The system of claim 1, wherein the microprocessor is programmed to perform credit card transactions; wherein the microprocessor is programmed to measure electricity dispensed through the outlet portion; and wherein the microprocessor is programmed to mathematically convert the measured electricity dispensed into a dollar amount to be charged to a credit card.

3. The system of claim 1 wherein the energy storage system includes at least one battery.

4. The system of claim 1 wherein the energy storage system is a power grid.

5. The system of claim 1 and further comprising:
an anchor portion connected to the first support member;
an armature connected to the first support member and to the at least one solar panel;
wherein the armature includes at least one joint for positioning the solar panel.

6. The system of claim 1 and further comprising:
a generally horizontally extending second support member connected near the distal end of the first support member;
an anchor portion connected to the first support member;
an armature connected to the second support member and to the at least one solar panel;
wherein the armature includes at least one joint for positioning the solar panel.

7. The system of claim 5 wherein the armature pivots to aim the solar panel at the sun.

8. The system of claim 5 wherein the armature pivots to simultaneously aim the solar panel at the sun and to maintain parking shade on a predetermined parking space.

9. The system of claim 8 wherein the armature is substantially constantly and automatically pivoted to maintain aim of the solar panel at the sun and to maintain shade on the predetermined parking space.

10. A system for automatically providing shade to a parking space and transducing incident energy into electricity for storage and redistribution, comprising:
a transaction portion, further comprising;
a housing;
a microprocessor portion positioned in the housing and operationally connected to a computer network;
an energy metering portion positioned in the housing and operationally connected to the microprocessor;
an energy inlet portion operationally connected to the housing and the energy metering portion; and
an energy outlet portion operationally connected to the housing, the energy inlet portion and the energy metering portion; and
an energy storage portion operationally connected to the energy inlet portion and to the energy outlet portion; and
an energy source operationally connected to the energy inlet portion.

11. The system of claim 10, wherein the microprocessor is programmed to perform credit card transactions; wherein the microprocessor is programmed to measure electricity dispensed through the outlet portion; and wherein the microprocessor is programmed to mathematically convert the measured electricity dispensed into a dollar amount to be charged to a credit card.

12. The system of claim 10 wherein the energy storage system includes at least one battery.

13. The system of claim 10 wherein the energy storage system is a power grid.

14. The system of claim 10 wherein the energy source is at least one solar collector.

15. The system of claim 10 wherein the energy source is a thermoelectric transducer for directly converting heat into electricity.

16. The system of claim 10 wherein the energy source is a vehicle.

17. The system of claim 16 and further comprising:
a support member;
an anchor portion connected to the support member;
an armature connected to the support member and to the at least one solar panel;
wherein the armature includes at least one joint for positioning the solar panel.

18. A method of renting shade to parking customers by transducing incident sunlight into electricity, comprising:
a) erecting a plurality of transducing shade structures, each respective structure further comprising:
a housing;
a microprocessor mounted in the housing connected in electric communication with a computer network;
an energy meter mounted in the housing and connected in electric communication with the microprocessor;
a timer mounted in the housing and connected in electric communication with the microprocessor;
an input panel mounted to the housing and connected in electric communication with eh microprocessor;
an energy inlet connected to the housing;
an energy outlet connected to the housing, to the energy inlet and to the energy meter;
an energy storage system electrically connected to the energy inlet and to the energy outlet; and
a solar panel electrically connected to the energy inlet;
b) transducing sunlight into electricity;
c) flowing electricity from the solar panel into the energy storage system;
d) shading a parking space;
e) renting shaded parking space to a parking customer;
f) identifying an energy user; and
g) selling energy to the energy user.

19. The method of claim 18 and further comprising:
h) measuring the dispensed energy; and
i) debiting the energy user for the dispensed energy;
wherein step g) includes dispensing energy to an energy user through the energy outlet at the transaction unit.

20. The method of claim 18 wherein the energy outlet is connected to a power grid and wherein the energy user is an electric utility.

21. The method of claim 18 wherein step d) further comprises automatically orienting the solar panel to simultaneously maximize incident sunlight and maximize shading a pre-assigned parking space.
